(19) United States
(12) Patent Application Publication
(10) Pub. No.: US 2008/0185176 A1
(43) Pub. Date: Aug. 7, 2008

(54) Wiring Board Member For Forming Multilayer Wiring Board, Method of Manufacturing the Same, and Multilayer Wiring Board

(76) Inventor: Junichi Hagihara, Yamanashi-Ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 10/562,923

(22) PCT Filed: Jun. 29, 2004
(86) PCT No.: PCT/JP2004/009150

§ 371 Date: Mar. 31, 2008

(30) Foreign Application Priority Data
Jul. 1, 2003 (JP) 2003-270043

(51) Int. Cl. H05K 1/11; H01B 13/00; H05K 3/46

(52) U.S. Cl. 174/262; 216/18

(57) ABSTRACT

A wiring board member for forming a multilayer wiring board includes an insulation layer (11) having a hole (11a) and a metal layer (12) as a conductive layer joined to the insulation layer. The metal layer (12) includes a via portion (12b) occupying the hold of the insulation layer, a bump portion (12a) integrally connected to the via portion, and a wiring part (12c). The bump portion is disposed on one surface of the insulation layer, and has a substantially truncated quadrangular pyramid shape with a bottom surface thereof being integrally connected to the via portion. The wiring part is disposed on the other surface of the insulation layer, and has a certain pattern.

### FIELD OF THE INVENTION

The present invention relates to a wiring board member for forming a multilayer wiring board, a method of manufacturing the same, and a multilayer wiring board formed with the use of the wiring board member.

### BACKGROUND ART

In order to manufacture a highly integrated wiring board, it is necessary to make finer a wiring circuit formed in the wiring board, to laminate such wiring boards to each other, and to finely form a connection between the upper and lower wirings at a high reliability. A so-called build-up method has been known as a method of manufacturing such a multilayer wiring board. In this method, a printed wiring board (core board) is made by collectively unifying laminated materials in which wiring patterns have been formed, and forming through-holes by a drill or the like to provide connections between the layers. Then, an insulation layer and a wiring layer are alternately formed on the core board to realize a fine wiring.

However, the build-up method is disadvantageous in the large number of steps and an increased manufacturing cost. Further, it is difficult to drill a through-hole of a smaller diameter in the laminated materials forming the core board. Furthermore, since the through-hole is an obstacle to a wiring, the wiring must be formed to bypass the through-hole. Thus, a wiring of a higher density cannot be achieved.

As one of the means for coping with these problems, there is a method of manufacturing a multilayer wiring board described in JP2002-359471A. In this method, there are firstly prepared a plurality of multilayer metal plates each of which is formed by laminating a metal layer or a wiring film or a wiring film, to a metal layer for bumps, through an etching stop layer. Then, the metal layer for bumps of a first multilayer metal plate is pattered to form thereon bumps, and an insulation layer is formed on the surface on which the bumps have been formed such that only tops of the bumps are exposed. Thereafter, the first multilayer metal plate and a second multilayer metal plate are laminated such that the bumps on the first multilayer metal plate and the wiring layer of the second multilayer metal plate are opposed to each other. Following thereto, the metal layer for bumps of the second multilayer metal plate is patterned to form thereon bumps, and an insulation layer is formed on the surface on which the bumps have been formed such that only tops of the bumps are exposed. Thereafter, the second multilayer metal plate and a third multilayer metal plate are laminated such that the bumps on the second multilayer metal plate and the wiring layer of the third multilayer metal plate are opposed to each other. By repeating these steps, a multilayer wiring board is manufactured.

In this method of manufacturing a multilayer wiring board, the bumps are formed on the multilayer metal plate by an etching process. Thus, it is difficult to improve a shaping accuracy of the bumps, resulting in fluctuations in the shape of the bumps. In addition, it is difficult to form fine bumps, which prevents formation of a finer wiring of a higher density.

### DISCLOSURE OF THE INVENTION

The present invention has been made in view of the above circumstances. The object of the present invention is to provide a wiring board member having a bump portion excellent in positioning accuracy and shaping accuracy, the wiring board member thus being capable of forming a multilayer wiring board which enables a finer wiring of a higher density.

Another object of the present invention is to provide a manufacturing method of manufacturing such a wiring board member at a low cost, and a multilayer wiring board formed with the use of such a wiring board member.

According to the present invention, there is provided a wiring board member for forming a multilayer wiring board, comprising: an insulation layer having a hole passing through the insulation layer in a thickness direction thereof; and a conductive layer joined to the insulation layer; wherein the conductive layer includes: a via portion occupying the hole in the insulation layer; a bump portion disposed on one surface of the insulation layer, the bump portion having a substantially quadrangular pyramid shape or a substantially truncated quadrangular pyramid shape with a bottom surface thereof integrally connected to the via portion; and a wiring part having a certain pattern, the wiring part being disposed on the other surface of the insulation layer, and being integrally connected to the via portion.

The wiring board member has an excellent bump positioning accuracy and an excellent bump shaping accuracy. By using this wiring board member, it is possible to form a multilayer wiring board enabling a finer wiring of a higher density.

According to the present invention, there is provided a method of manufacturing the wiring board member for forming such a multilayer wiring board. Namely, there is provided a method of manufacturing a wiring board member for forming a multilayer wiring board, comprising: a step of forming a mask having a certain opening pattern on a surface of a silicon substrate whose main surface is (100) face; a step of forming a recess of a substantially quadrangular pyramid shape or a substantially truncated quadrangular pyramid shape on a surface of the silicon substrate, by a crystal anisotropy etching of the silicon substrate through the mask with a chemical liquid; a step of removing the mask from the surface of the silicon substrate; a step of forming an insulation layer on the surface of the silicon substrate other than a part where the recess is formed in the silicon substrate; a step of forming a conductive layer on the surface of the silicon substrate on which the insulation layer have been formed, the conductive layer covering the insulation layer and occupying the recess; and a step of separating the insulation layer and the conductive layer from the silicon substrate to obtain a wiring board member including the insulation layer and the conductive layer.

According to the manufacturing method, by using as a mold the silicon substrate provided with the recess, the wiring board member having a bump portion excellent in positioning accuracy and shaping accuracy can be economically manufactured at a high reproducibility. Further, it is easy to make finer the bump portion, whereby a finer wiring of a higher density can be attained. Moreover, the silicon substrate used when manufacturing the first wiring board member can be reused to manufacture again the same wiring board member, whereby productivity can be raised.

According to the present invention, there is provided a multilayer wiring board that is manufactured with the use of such a wiring board member. Namely, there is provided a multilayer wiring board formed with the use of a wiring board member, wherein the wiring board member comprising: an insulation layer having a hole passing through the insulation layer in a thickness direction thereof; and a conductive layer joined to the insulation layer; wherein the conductive layer includes: a via portion occupying the hole in the insulation layer; a bump portion disposed on one surface of the insulation layer, the bump portion having a substantially quadrangular pyramid shape or a substantially truncated quadrangular pyramid shape with a bottom surface thereof integrally connected to the via portion; and a wiring part having a certain pattern, the wiring part being disposed on the other surface of the insulation layer, and being integrally connected to the via portion.

As described above, with the use of the wiring board member having the bump portion excellent in positioning accuracy and shaping accuracy, the multilayer wiring board can be manufactured by readily conducting a process of multilayer formation. Thus, a highly integrated multilayer wiring board can be inexpensively provided.

Since the bump portion has a tapered shape of a substantially quadrangular pyramid or a substantially truncated quadrangular pyramid, the wiring board member according to the present invention can be connected to a narrower wiring part. Thus, a finer wiring pattern can be made at a higher integration. Due to a smaller area of a distal end of the bump portion, a pressure applied by a heat-pressing can be decreased when a multilayer wiring board is formed with the use of the wiring board member. As a result, damage to the multilayer wiring board to be formed can be alleviated.

### BRIEF DESCRIPTION OF THE DRAWINGS

FIG. 1 is a schematic sectional view of a wiring board member for forming a multilayer wiring board, according to the present invention;

FIG. 2 is a flowchart of a method of manufacturing the wiring board member shown in FIG. 1;

FIG. 3 shows the method of manufacturing the wiring board member shown in FIG. 2 by sequential schematic sectional views (a) to (h);

FIG. 4 shows the method of manufacturing the wiring board member shown in FIG. 2 by sequential schematic sectional views (i) to (n);

FIG. 5 is a schematic sectional view of a recess of an alternative example of a recess shown in FIG. 3(e);

FIG. 6 is a schematic view of a modification of the wiring board member suitable for the recess shown in FIG. 5; and

FIG. 7 shows a method of manufacturing a multilayer wiring board with the use of the wiring board member according to the present invention, by sequential schematic views (a) to (f).

### BEST MODE FOR CARRYING OUT THE INVENTION

Embodiments of the present invention will be described in detail with reference to the accompanying drawings.

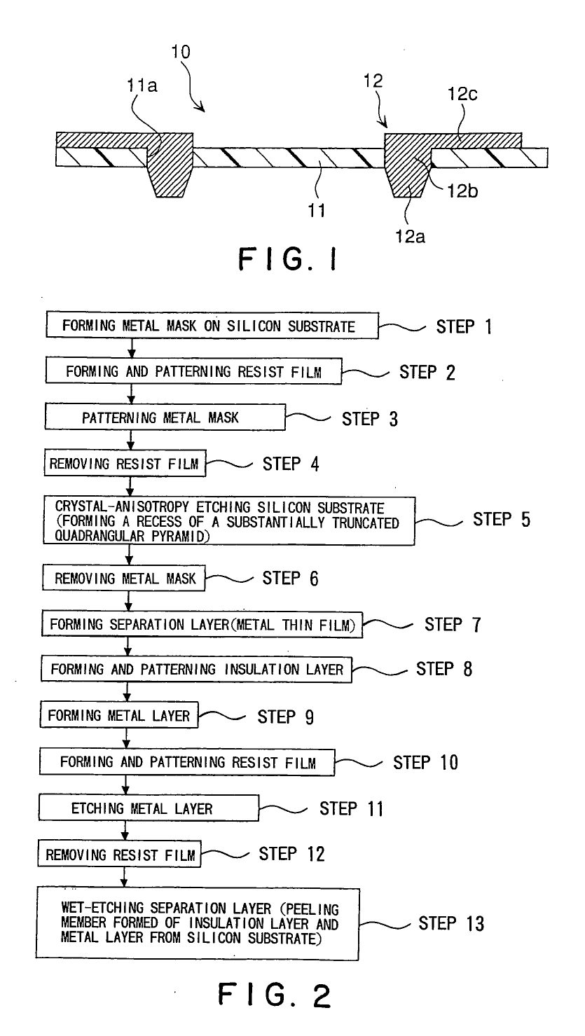

FIG. 1 shows an embodiment of a wiring board member for forming a multilayer wiring board according to the present invention. A wiring board member 10 shown in FIG. 1 includes an insulation layer 11 having a hole 11a formed in a predetermined position to pass through the insulation layer 11 in a thickness direction thereof, and a metal layer 12 as a conductive layer joined to the insulation layer 11. The metal layer 12 includes a via portion 12b occupying the hole 11a in the insulation layer 11, a bump portion 12a integrally connected to the via portion 12b, and a wiring part 12c. The bump portion is disposed on one surface of the insulation layer 11, and has a substantially truncated quadrangular pyramid shape with a bottom surface thereof integrally connected to the via portion 12b. The wiring part 12c is formed on the other surface (opposite surface) of the insulation layer 11, and has a certain circuit pattern. Preferably, an opening shape of the hole 11a is of a substantially square shape.

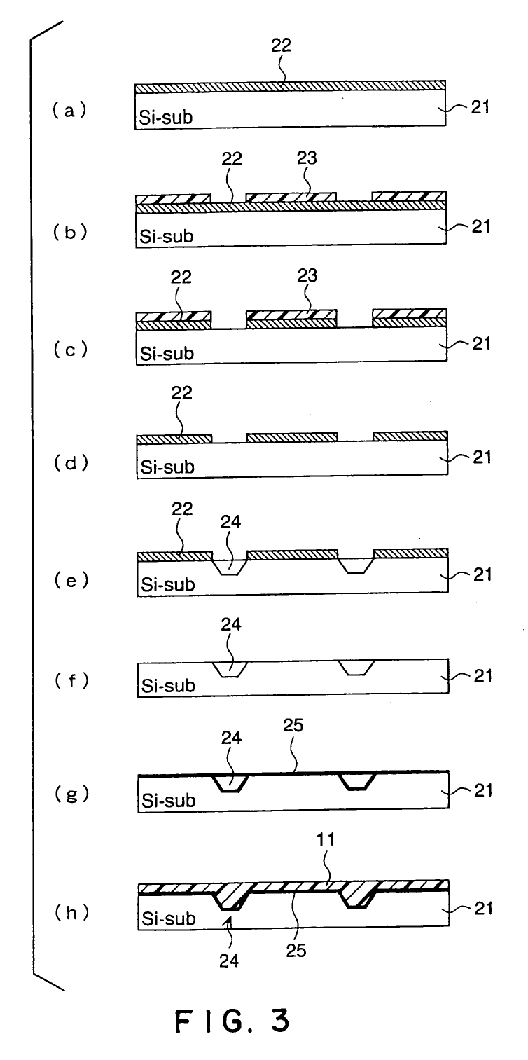

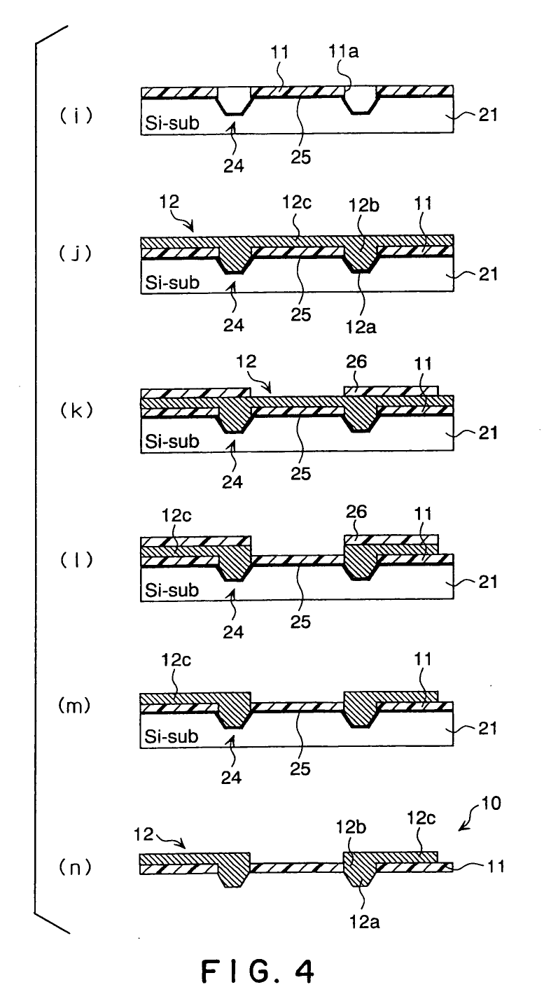

Next, as an embodiment of a method of manufacturing a wiring board member according to the present invention, a method of manufacturing the wiring board member 10 shown in FIG. 1 is described with reference to FIGS. 3 and 4 along with the flowchart shown in FIG. 2.

At first, as shown in FIG. 3(a), a silicon substrate 21 (depicted as “Si-sub” in FIG. 3) whose main surface is a Miller indices (100) face is prepared. Then, a metal film 22 (referred to as “metal mask 22” below), which will be used as a mask afterward, is formed on the main surface of the silicon substrate 21 (step 1 in FIG. 2). As described below, it is necessary to select as a material of the metal mask 22 a material that is not dissolved by a chemical liquid which is used afterward for conducting a crystal anisotropy etching of the silicon substrate 21.

Then, as shown in FIG. 3(b), by using a photolithography technique, a resist film 23 is formed on a surface of the metal mask 22 by, e.g., a spin coating method. The resist film 23 is patterned by exposing, developing, and heat-processing the same so as to form thereon a predetermined pattern (step 2). The patterning of the resist film 23 is conducted such that a substantially square-shaped hole is formed at a predetermined position. Subsequently, as shown in FIG. 3(c), the metal mask 22 is etched by using the patterned resist film 23 as an etching mask, so that the metal mask 22 is patterned (step 3). Then, as shown in FIG. 3(d), the resist film 23 is removed from the silicon substrate 21 by, e.g., an ashing or a chemical-liquid processing (step 4).

Thereafter, as shown in FIG. 3(e), the silicon substrate 21 is etched through the patterned metal mask 22 (step 5) by using a chemical liquid (etchant). As the etchant, a potassium hydroxide (KOH) solution, an ethylenediamine.pyrocatechol (EDP) solution, or a tetramethyl ammonium hydroxide (TMAH) solution is preferably used. The etching process in the step 5 is a crystal anisotropy etching which depends on a crystal structure of the silicon substrate 21 to form a recess of a substantially quadrangular pyramid shape. By conducting such an etching for a predetermined period of time, a recess 24 of a substantially truncated quadrangular pyramid shape is formed in the silicon substrate 21. A side surface of the recess 24 makes an angle of about 54.7 degrees with the (100) face of the silicon substrate 21.

The metal mask 22 is required to be resistive to the etchant used in the process in step 5. When a potassium hydroxide (KOH) solution is used as the etchant, the metal mask 22 is preferably made of Pt/Ti. When an ethylenediamine.pyrocatechol (EDP) solution is used, the metal mask 22 is preferably made of Ti, TiN, TiN/Ti, Cr, Ta, Nb, Zr, Pt/Ti, Pt/Cr, Au/Ti, or Au/Cr. When a tetramethyl ammonium hydroxide (TMAH) solution is used, the metal mask 22 is preferably made of Cr, Mo, Zr, TiN/Ti, Ni/Cr, Pt/Cr, or Au/Cr.

After the recess 24 is formed in the silicon substrate 21, as shown in FIG. 3(f), the metal mask 22 is removed from the silicon substrate 21 by an etching process (step 6). Then, as shown in FIG. 3(g), a separation layer 25 of a metal thin film, which is dissolved by a predetermined chemical liquid, is formed on a surface of the silicon substrate 21 including a surface of the recess 22 by a spattering method or the like (step 7). A function of the separation layer 25 is to facilitate peeling of the insulation layer 11 and the metal layer 12 together, which will be formed on the silicon substrate 21 afterward, from the silicon substrate 21.

Then, as shown in FIG. 3(h), the insulation layer 11 is formed on the separation layer 25. Thereafter, as shown in FIG. 4(i), the insulation layer 11 is patterned (step 8). This patterning is conducted such that the insulation layer 11 remains only on a part of the surface of the separation layer 25 other than a part where the recess 24 is formed in the silicon substrate 21. In other words, a part of the insulation layer 11 corresponding to the recess 24 of the silicon substrate 21 is removed, so that the insulation film 11 has the hole 11a corresponding to the recess 24. Such a patterning can be conducted by forming the insulation layer 11 of a resist film, and then by exposing and developing a part of the resist film forming the hole 11a so as to remove the part.

Then, as shown in FIG. 4(j), the metal layer 12 is formed on the insulation layer 11 by, e.g., a plating method such that the recess 24 and the hole 11a are filled with the metal layer 12 (step 9). As a material of the metal layer 12, copper or copper alloy is preferably used. When the metal layer 12 is formed by a plating method, prior to the plating process, a surface of the insulation layer 11 is roughened by an ashing, and a seed layer is formed by, e.g., a spattering method. The thus formed metal layer 12 has a one-piece structure including the bump portion 12a of a substantially truncated quadrangular pyramid which occupies the recess 24, the via portion 12b which occupies the hole 11a, and the wiring part 12c to be formed into a predetermined pattern afterward (through the separation layer 25).

Then, as shown in FIG. 4(k), a resist film 26 is further formed on a surface of the metal layer 12 by using a photolithography technique. Then, the resist film 26 is patterned by exposing and developing the same to form a predetermined pattern (step 10). Thereafter, as shown in FIG. 4(l), the metal layer 12 is etched by using the patterned resist film 26 as a mask (step S11). Thus, the wiring part 12c of the metal layer 12 forms a predetermined wiring pattern.

Then, as shown in FIG. 4(m), the resist film 26 is removed from the metal layer 12 by, e.g., an ashing or a chemical-liquid processing (step 12). In this step, it is necessary to determine materials of the insulation layer 11 and the resist film 26 and a removing method of the resist film 26, in order not to remove the insulation layer 11 as a resist film together with the resist film 26. Hereupon, the wiring board member 10 shown in FIG. 1 is formed on the silicon substrate 21 through the separation layer 25. Then, as shown in FIG. 4(n), the separation layer 25 is removed from the silicon substrate 21 by a wet etching (step 13). Due to this process, the insulation layer 11 and the metal layer 12 are separated together from the silicon substrate 21, whereby the wiring board member 10 formed of the insulation layer 11 and the metal layer 12, which is shown in FIG. 1, can be provided.

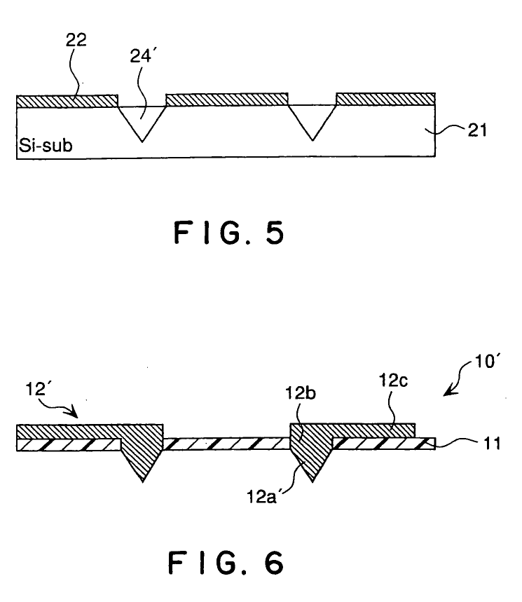

In the above-described crystal-anisotropy etching process (step 5), as shown in FIG. 5, it is possible to form a recess 24′ of a substantially quadrangular pyramid shape in the silicon substrate 21 by elongating the etching period. By conducting the processes following to the step 6 with the silicon substrate 21 having the recess 24′, it is possible to manufacture a wiring board member 10′ including a metal layer 12′ provided with a bump portion 12a′ of a substantially quadrangular pyramid shape, which is shown in FIG. 6. A depth of the recess 24′ is determined by the dimensions of the hole 11a (edge length). The wiring board member 10′ can be used similarly to the wiring board member 10 shown in FIG. 1.

According to the method of manufacturing a wiring board member, the bump portion 12a can be formed with a positioning accuracy identical to a positioning accuracy of the photolithography technique. Thus, it is possible to easily form the fine bump portion 12a suitable for the wiring part 12c whose pattern is as fine as 5 to 10 μm in dimension. At the same time, by utilizing a crystal anisotropy etching of the silicon substrate 21, it is possible to constantly form the bump portions 12a of the same shape. That is to say, it is possible to form the bump portion 12a excellent in positioning accuracy and shaping accuracy. Further, since a height of the bump portion 12a can be adjusted by changing a period of the crystal-anisotropy etching process, an area of a distal end of the bump portion 12a (base area of the truncated quadrangular pyramid on a distal end side thereof) can be adjusted. Namely, even when a width of a wiring to be connected to the distal end of the bump portion 12a is small, it is possible to form the bump portion 12a suitable for the narrow wiring. Thus, a wiring pattern can be made finer, and an integration thereof can be made higher. Furthermore, the silicon substrate 21 in which the recess 24 has been formed (FIG. 3(f)) can be reused for manufacturing another wiring board member 10.

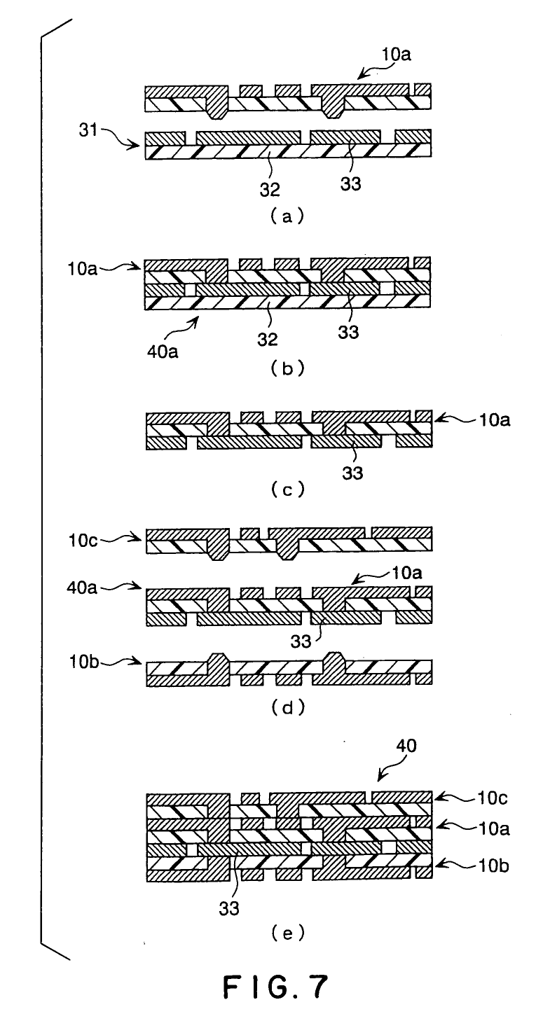

Next, with reference to FIG. 7, there will be described a method of manufacturing a multilayer wiring board 40 with the use of three wiring board members 10a to 10c which have been provided by the above-described manufacturing method. At first, a Cu/PI sheet (wiring sheet) 31 is prepared, in addition to the wiring board members 10a to 10c. The Cu/PI sheet 31 includes a polyimide (PI) sheet 32 as a flat insulation film, and a copper wiring 33 formed on the PI sheet 32 and constituting a wiring pattern.

Then, as shown in FIG. 7(a), the Cu/PI sheet 31 and the wiring board member 10a are stacked such that the copper wiring 33 of the CU/PI sheet 31 and the bump portions of the wiring board member 10a are opposed to each other. Then, the Cu/PI sheet 31 and the wiring board member 10a are heat-pressed. Thus, as shown in FIG. 7(b), there is obtained a multilayer wiring board 40a which is a layer body including the CU/PI sheet 31 and the wiring board member 10a. Since the bump portion of the wiring board member 10a has a tapered shape, the bump portions and the copper wiring 33 of the Cu/PI sheet 31 can be connected to each other at a relatively lower pressure upon the heat-pressing. Thus, damage to the wiring board member 10a and the Cu/PI sheet 31 can be alleviated. During the heat-pressing, the bump portions stick into the copper wiring 33 and collapse.

Then, as shown in FIG. 7(c), the PI sheet 32 is peeled from the multilayer wiring board 40a. Thereafter, as shown in FIG. 7(d), the wiring board member 10b is stacked on the multilayer wiring board 40a such that the bump portions of the wiring board member 10b face the copper wiring 33, and the wiring board member 10c is stacked on the multilayer wiring board 40a such that the bump portions of the wiring board member 10c face the wiring part of the wiring board member 10a. Then, the wiring board member 10c, the multilayer wiring board 40a, and the wiring board member 10b are heat-pressed. Thus, as shown in FIG. 7(e), there is obtained a multilayer wiring board 40 in which the multilayer wiring board 40a and the wiring board members 10b and 10c are laminated to each other.

By repeating the above steps for manufacturing the multilayer wiring board 40 from the multilayer wiring board 40a, i.e., by further laminating another wiring board member to a surface of the multilayer wiring board 40, a multilayer wiring board having the larger number of layers can be obtained. FIG. 7 illustrates that each of the wiring board members 10b and 10c previously has a wiring part of a certain pattern. However, patterns of the wiring parts of the wiring board members 10b and 10c may be formed after the multilayer wiring board 40 is manufactured. For example, patterns of the wiring parts of the wiring board members 10b and 10c may be formed by subjecting the front and rear surfaces of the multilayer wiring board 40 to a series of processes, such as formation of a mask, etching, and removal of the mask.

As described above, it is possible to manufacture a multilayer wiring board having a fine wiring pattern can be manufactured with an increased throughput, by manufacturing the multilayer wiring board with the use of the wiring board member according to the present invention. Another known method of manufacturing a multilayer wiring board is a method using a solder ball. In this method, a wiring region in which a solder ball is placed must be larger than a diameter of the solder ball, because of the need for considering fusion of the solder ball. Thus, it is difficult to form a wiring of a higher integration. On the other hand, when a multilayer wiring board is manufactured with the use of a wiring board member according to the present invention, since a bump portion has a tapered shape, an integration of a wiring can be made higher by narrowing a region of a wiring part to be connected to the bump portion. Moreover, since a solder ball is a metal heterologous to copper, the solder ball is inappropriate to increase a speed of a device. On the other hand, the present invention can achieve joining of the homogenous metals, i.e., a Cu—Cu joining.

Further, as is apparent from in the left side part of the multilayer wiring board 40 shown in FIG. 7(e), it is easy to form with a bulk copper a wiring passing through a portion between a front surface and a rear surface of the multilayer wiring board 40. It is also easy to form a wiring at a portion between some layers with a bulk copper or a bulk copper alloy. A known conventional method of forming a wiring passing through a front surface and a rear surface of a multilayer wiring board is a method of forming a through-hole in the multilayer wiring board and plating an inner surface of the through-hole. Since the existence of such a through-hole needs another wiring to bypass the through-hole, a higher density of the wiring cannot be attained. On the other hand, when a multilayer wiring board is manufactured with the use of a wiring board member according to the present invention, bypassing a wiring can be easily avoided.

The present invention is not limited to the above-described embodiments. For example, in the method of manufacturing the wiring board member 10 (step 1), although the metal mask 22 is formed on the surface of the silicon substrate 21, a silicon oxide film (SiO₂ film) may be formed in place of the metal mask 22, and the film may be patterned with a predetermined method. The patterned SiO₂ film can be used as a mask when the silicon substrate 21 is subjected to the crystal anisotropy etching (step 5).

In addition, in the method of manufacturing the wiring board member 10 (step 8), a resist film is formed as the insulation layer 11. However, a low-k film such as a porous SiO₂ film may be formed as the insulation layer 11. In this case, a resist film of a predetermined pattern may be formed on a surface of the low-k film, the low-k film may be etched or ashed using the resist film as a mask to form thereon a pattern, and the resist film may be removed.

1. A wiring board member for forming a multilayer wiring board, comprising:
an insulation layer having a hole passing through the insulation layer in a thickness direction thereof; and
a conductive layer joined to the insulation layer;
wherein the conductive layer includes:
a via portion occupying the hole in the insulation layer;
a bump portion disposed on one surface of the insulation layer, the bump portion having a substantially quadrangular pyramid shape or a substantially truncated quadrangular pyramid shape with a bottom surface thereof integrally connected to the via portion; and
a wiring part having a certain pattern, the wiring part being disposed on the other surface of the insulation layer, and being integrally connected to the via portion.

2. The wiring board member according to claim 1,
wherein the insulation layer is a resist film.

3. The wiring board member according to claim 1,
wherein the conductive layer is made of copper or copper alloy.

4. A method of manufacturing a wiring board member for forming a multilayer wiring board, comprising:
a step of forming a mask having a certain opening pattern on a surface of a silicon substrate whose main surface is (100) face;
a step of forming a recess of a substantially quadrangular pyramid shape or a substantially truncated quadrangular pyramid shape on a surface of the silicon substrate, by a crystal anisotropy etching of the silicon substrate through the mask with a chemical liquid;
a step of removing the mask from the surface of the silicon substrate;
a step of forming an insulation layer on the surface of the silicon substrate other than a part where the recess is formed in the silicon substrate;
a step of forming a conductive layer on the surface of the silicon substrate on which the insulation layer have been formed, the conductive layer covering the insulation layer and occupying the recess; and
a step of separating the insulation layer and the conductive layer from the silicon substrate to obtain a wiring board member including the insulation layer and the conductive layer.

5. The method of manufacturing a wiring board member according to claim 4, further comprising, between the step of removing the mask and the step of forming the insulation layer, a step of forming a separation layer on the surface of the silicon substrate for facilitating separation of the insulation layer and the conductive layer from the silicon substrate.

6. The method of manufacturing a wiring board member according to claim 5,
wherein the step of separating the insulation layer and the conductive layer from the silicon substrate is conducted by dissolving the separation layer by a process liquid.

7. The method of manufacturing a wiring board member according to claim 4, further comprising a step of forming a certain wiring pattern in the conductive layer.

8. The method of manufacturing a wiring board member according to claim 4,
wherein the mask is formed of a metal film.

9. The method of manufacturing a wiring board member according to claim 4,
wherein the mask is formed of a silicon oxide film.

10. The method of manufacturing a wiring board member according to claim 4,
wherein the chemical liquid is selected from the group consisting of a potassium hydroxide solution, an ethylenediamine.pyrocatechol solution, and a tetramethyl ammonium hydroxide solution.

11. The method of manufacturing a wiring board member according to claim 4,
wherein the insulation film is a resist film.

12. The method of manufacturing a wiring board member according to claim 4,
wherein the step of forming the conductive layer is conducted by a plating with copper or copper alloy.

13. A multilayer wiring board formed with the use of a wiring board member,
wherein the wiring board member comprising:
an insulation layer having a hole passing through the insulation layer in a thickness direction thereof; and
a conductive layer joined to the insulation layer;
wherein the conductive layer includes:
a via portion occupying the hole in the insulation layer;
a bump portion disposed on one surface of the insulation layer, the bump portion having a substantially quadrangular pyramid shape or a substantially truncated quadrangular pyramid shape with a bottom surface thereof integrally connected to the via portion; and
a wiring part having a certain pattern, the wiring part being disposed on the other surface of the insulation layer, and being integrally connected to the via portion.

14. The multilayer wiring board according to claim 13, comprising a layered body including the plurality of wiring board members that differ from each other in a position of the hole or the pattern of the wiring part, the wiring board members being stacked on each other and unified together.

15. The multilayer wiring board according to claim 13 comprising a layered body including:
the wiring board member: and
a wiring sheet having a flat insulation film and a wiring pattern formed on the insulation film;
the wiring board member and the wiring sheet being stacked on each other and unified together.
